(19) United States
(12) Patent Application Publication
(10) Pub. No.: US 2021/0042607 A1
(43) Pub. Date: Feb. 11, 2021

(54) CROSS-DOMAIN METRIC LEARNING SYSTEM AND METHOD

(71) Applicant: Robert Bosch GmbH, Stuttgart (DE)

(72) Inventors: Zhixin YAN, Sunnyvale, CA (US); Mao YE, San Jose, CA (US); Liu REN, Cupertino, CA (US)

(21) Appl. No.: 16/531,630

(22) Filed: Aug. 5, 2019

(51) Int. Cl. G06N 3/04; G06F 17/16; G06T 19/00; G06N 20/00

(52) U.S. Cl. CPC G06N 3/0454; G06N 20/00; G06T 19/006; G06F 17/16

(57) ABSTRACT

An augmented reality (AR) system and method is disclosed that may include a controller operable to process one or more convolutional neural networks (CNN) and a visualization device operable to acquire one or more 2-D RGB images. The controller may generate an anchor vector in a semantic space in response to an anchor image being provided to a first convolutional neural network (CNN). The anchor image may be one of the 2-D RGB images. The controller may generate a positive vector and negative vector in the semantic space in response to a negative image and positive image being provided to a second CNN. The negative and positive images may be provided as 3-D CAD images. The controller may apply a cross-domain deep metric learning algorithm that is operable to extract image features in the semantic space using the anchor vector, positive vector, and negative vector.

### TECHNICAL FIELD

The following relates generally to a machine learning augmented reality (AR) system and method.

### BACKGROUND

Machine learning (ML) algorithms arc generally operable to perform a given task using patterns and inferences. Machine learning algorithms are generally based on a mathematical model that relies on “training data” to make predictions or decisions without being explicitly programmed to perform the requested task.

### SUMMARY

In one embodiment, an augmented reality system (AR system) and method is disclosed that may include a controller operable to process one or more convolutional neural networks (CNN) and a visualization device operable to acquire one or more two-dimensional RGB images. The controller may also generate an anchor vector in a semantic space in response to an anchor image being provided to a first convolutional neural network (CNN). The anchor image may be one of the two-dimensional RGB images acquired by the visualization device. The controller may also generate a positive vector and negative vector in the semantic space in response to a negative image and positive image being provided to a second CNN. The negative image may be a first three-dimensional computer-aided design (CAD) image and the positive image may be a second three-dimensional CAD image. Both the first CAD image and second CAD image may be provided to the AR system from a database.

It is contemplated that the first CNN and the second CNN may include one or more second convolutional layers, one or more second max pooling layers, a second flattening layer, a second dropout layer, and a second fully connected layer. It is also contemplated that the controller may apply a cross-metric deep metric learning algorithm that is operable to extract image features in the semantic space using the anchor image, positive image, and negative image. It is further contemplated that the controller may be operable to extract one or more image features from different modalities using the anchor vector, positive vector, and negative vector

The cross-domain deep metric learning algorithm may be implemented as a triplet loss algorithm that is operable to decrease a first distance between the anchor vector and the positive vector in the semantic space and increase a second distance between the anchor vector and the negative vector in the semantic space. Also, the convolutional layers included within the first CNN and second CNN may be implemented using one or more activation functions that may include a rectified linear unit.

It is contemplated that the first and CNN and second CNN may employ skip-connection architecture. The second CNN may also be designed as a Siamese network. The controller may perform step recognition by analyzing the image features extracted in the semantic space. Lastly, the controller may also be operable to determine if an invalid repair sequence has occurred based on an analysis of the image features in the semantic space.

It is contemplated that the controller may further be operable to determine a pose of an image object within the one or more RGB images. The controller may also apply a post-processing image algorithm to the one or more RGB images.

### BRIEF DESCRIPTION OF THE DRAWINGS

FIG. 1 is an exemplary augmented reality (AR) system according to one embodiment;

FIGS. 2A and 2B are exemplary illustrations of the learning process for the triplet. loss function applied by the deep learning network;

FIG. 3 is an exemplary illustration of the convolutional neural network operating during a training phase;

FIG. 4 is an exemplary illustration of the convolutional neural network operating during a testing or run-time phase;

FIG. 5 is a illustration of an RGB image processed during the invalid step detection process; and

FIG. 6 is an illustration of bounding boxes identifying parts from an RGB image.

### DETAILED DESCRIPTION

As required, detailed embodiments are disclosed herein; however, it is to be understood that the disclosed embodiments are merely exemplary and may be embodied in various and alternative forms. The figures arc not necessarily to scale; some features may be exaggerated or minimized to show details of particular components. Therefore, specific structural and functional details disclosed herein are not to be interpreted as limiting, but merely as a representative basis for teaching one skilled in the art to variously employ the present embodiments.

It is contemplated that a vision-based AR system may be desirable that is operable to recognize the different status or steps of a work procedure (e.g., the correct steps needed to repair a vehicle). The vision-based AR system may be operable to recognize the different steps using 3-dimensional (3D) models of the entire procedure (e.g., 3-D models of the vehicle and the subset of vehicle parts). It is contemplated that the AR system may employ a machine learning algorithm that receives input data from different domains and encode the input data as high dimensional feature vectors. The machine learning algorithm may also be operable to transform the encoded features to one semantic space for distance measurement.

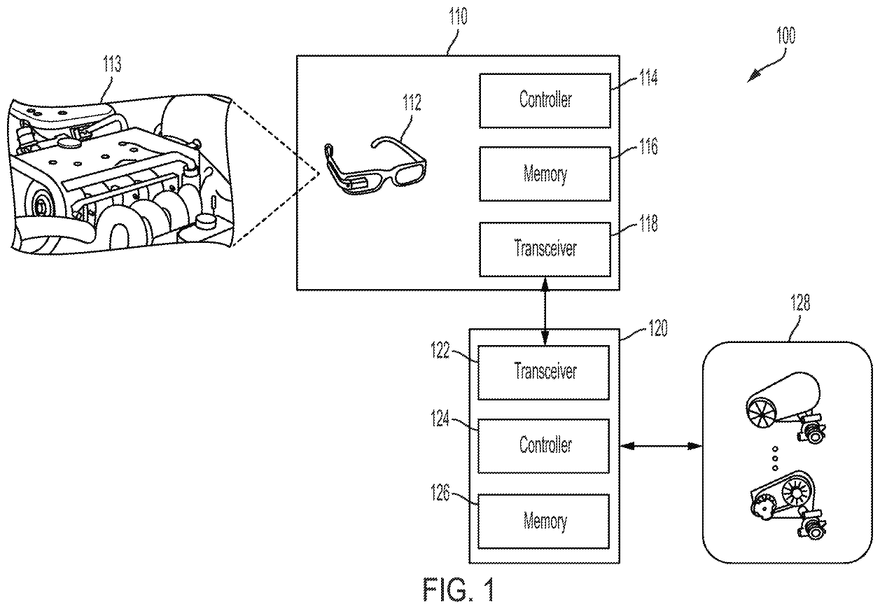

FIG. 1 illustrates an AR system 100 according to one exemplary embodiment. A client system 110 may include a visualization device 112 that may be operable for capturing one or more two-dimensional RGB images 113 (i.e., two-dimensional color images) when worn by the user. For instance, the visualization device 112 may include having a pair of AR glasses with an integrated digital camera or video camera operable to capture RGB images ) 113 (e.g., a DSLR camera or mirrorless digital camera).

The client system 110 may further include a controller 114 and memory 116. The controller 114 may be one or more computing devices such as a quad core processor for processing commands, such as a computer processor, microprocessor, or any other device, series of devices or other mechanisms capable of performing the operations discussed herein. The memory 116 may be operable to store instructions and commands. The instructions may be in the form of software, firmware, computer code, or some combination thereof. The memory 116 may be in any form of one or more data storage devices, such as volatile memory, non-volatile memory, electronic memory, magnetic memory, optical memory, or any other form of data storage device. The memory 116 may be an internal to client system 110 (e.g., DDR memory) or memory may comprise removable memory components (e.g., micro-SD card memory).

RGB images 113 may be captured by visualization device 112 for further processing by controller 114. For instance, the controller 114 may be operable to determine the position and orientation (i.e., pose) of the object captured by the RGB images 113 using visual odometry algorithms, simultaneous localization and mapping (SLAM) algorithms, and/or model-based tracking algorithms.

The client system 110 may be connected and in communication with a server system 120. For instance, client system 110 may include a client transceiver 118 operable to transmit and receive data using a wired network (e.g., LAN) or using a wireless network communication (e.g., WiFi, cellular Bluetooth, or Zigbee). Server system 120 may include a server transceiver 122 also operable to transmit and receive data using a wired network (e.g., LAN) or using a wireless network communication (e.g., WiFi, cellular, Bluetooth, or Zigbee). It is contemplated that the client transceiver 118 may be operable to transmit data, e.g., RGB images 113 and pose data, to the server transceiver 122. However, it is further contemplated that client system 110 and server system 120 may be included in one unit therefore not requiring the client transceiver 118 and server transceiver 122.

It is contemplated that the server system 120 may also include memory 126, like memory 116, for storing the RGB image 113 and pose data received from client system 110. The server system 120 may also include a controller 124, like controller 114, operable to perform post-processing algorithms on the RGB image 113. The server system 120 may also be connected and in communication with a database 128 for storing 3-dimensional computer aided design (3D-CAD) models (i.e., 3-D images) of the target work procedure. Server system 120 may communicate with database 128 using server transceiver 122. It is also contemplated that database 128 may be included within server system 120 therefore not requiring the server transceiver 124. Controller 124 may be operable to apply a computer graphic rendering algorithm that generates one or more normal map images of the 3D-CAD model that may be compared with the RGB images 113 based on the view defined by the pose data received from client system 110. Controller 124 may also be operable to apply post-processing image algorithms to the RGB image 113 received from client system 110.

Controller 124 may also be operable to apply one or more deep neural network (DNN) algorithms. It is contemplated that the controller 124 may apply a DNN status prediction algorithm using the normal map images and the RGB images 113 to predict the status of a work procedure (e.g., current step). The server system 120 may transmit instructions back to the client system 110 that may be visually displayed by visualization device 112.

It is contemplated that the DNN may be a convolutional neural net (CNN) that includes convolutional and pooling layers for handling image recognition applications. The CNN may be a two-branch CNN that is operable to obtain a bilinear feature vector for fine-grained classification. The CNN may also be operable to learn the proper features to compare the fine-grained categories of a given image. It is also contemplated that the machine learning algorithm may be operable to capture small variations in the important region of interests (ROO and to avoid noisy background images, illumination, and viewpoint changes. It is further contemplated that the controller 124 may be operable to employ deep metric learning (e.g., cross-domain deep metric learning) to further improve performance of the CNN by not constraining the recognition process to only the procedures provided during a training phase.

For instance, controller 124 may be operable to employ a CNN for determining the current step the user is performing and provide instructions for the next step the user will need to perform (i.e., “step recognition”). Controller 124 may also be operable to employ the CNN for detecting if a user's action deviates from. a prestored sequence of steps (i.e., “invalid step detection”). Upon detecting that the user has performed an invalid step, the controller 124 may transmit instructions to client system 110 to inform the user how to rectify any incorrect actions already taken. It is contemplated that the controller 124 may be operable to perform “step recognition” and “invalid step detection” using the 3D-CAD models stored in database 128 that correspond to the target work procedure being assessed.

It is contemplated that the CNN may be designed as a cross-domain deep metric learning algorithm that is trained to determine similarity measurements between the 2-D RGB images 113 acquired by the visualization device 112 and the 3D-CAD data stored in database 128. By training CNN, the controller 124 may be operable to compare the similarity or distance between the original data (i.e., the original 2-D images and 3-D CAD models) and the data transformed to the semantic space using a variation of the triplet loss algorithm as represented by Equation (1) below:

s(t)=Σᵢ^{N}[|f_{RGB}(xᵢ^{α})−f_{Normal}(xᵢ^{p})|₂²−|f_{RGB}(xᵢ^{α})−f_{Normal}(xᵢⁿ)|₂²+α]₊ (1)

Where Lₜᵣᵢₚₗₑₜ is the calculated triplet loss function, f_{RGB} is the branch of the CNN feature encoding of the RGB images 113, and f_{Normal} is the branch of the triplet loss function that extracts features from normal map images that are stored as 3D CAD models in database 128. It is contemplated that the triplet loss function may operate on a triplet of feature vectors which include an anchor image, a positive image, and a negative image.

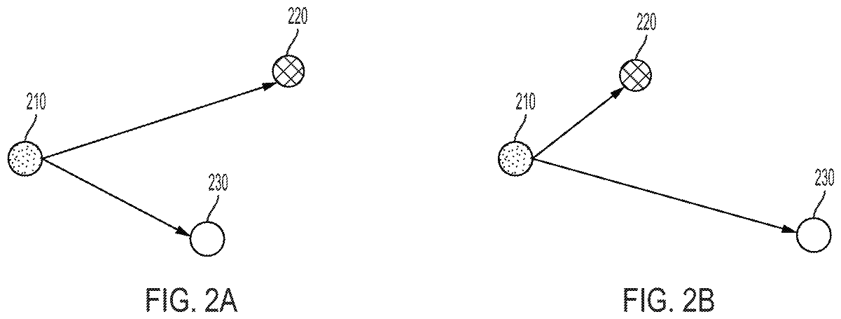

FIGS. 2A and 2B are exemplary illustrations of how the CNN may be trained using the triplet loss algorithm. Again, a triplet of the images may be generated that include an anchor image 210, a positive image 220, and a negative image 230. FIG. 2A illustrates that the distance of the positive image 220 to the anchor image 210 is greater than the distance from the negative image 230 and the anchor image 210. As shown by FIG. 2B, the CNN may apply the triplet loss function (Equation 1) to decrease the vector distance between the anchor image 210 and the positive image 220 and increase the distance the anchor image 210 and the negative image 230.

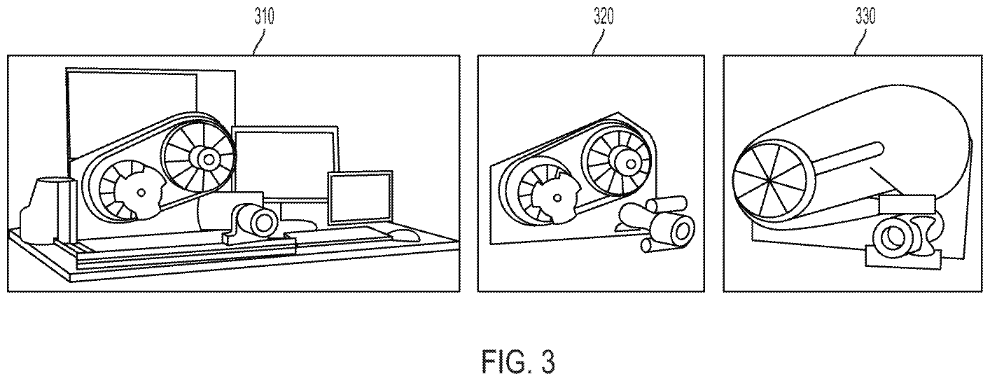

FIG. 3 illustrates an anchor image 310, positive image 320, and negative image 330 that may be used during the triplet loss algorithm. As illustrated, one of the RGB images 113 acquired by client system 110 may be assigned as the anchor image 310. The CNN may then receive the positive image 320 and negative image 330 from prestored normal map images that are generated by the 3D-CAD models stored in the database 128. The CNN algorithm may be trained to extract features from the anchor image 310 and the normal map images (i.e., the positive image 320 and negative image 330) in the semantic space.

It is also contemplated that the controller 124 may be operable to perform a two-branch CNN that extracts high dimensional features from the RGB images 113 acquired by the client system 110 and the normal map images that are stored as 3D-CAD models in database 128. It is contemplated that each branch of the CNN may include one or more convolution layers having kernels of various sizes (e.g., 3×3 or 5×5). The number and size of the kernels may be adjusted depending on a given application.

It is also contemplated that the CNN may include: one or more convolution layers employing a rectified linear unit (ReLU) or tanh as the activation functions; one or more normalization layers that are operable to improve the performance and stability of the CNN; and a max pooling layer that may reduce the dimensionality. The CNN may include one or more stacked modules based upon the complexity of the target data distribution. The CNN may also employ a skip-connection architecture where the output of one layer of the CNN may not be directly inputted to the next sequential layer of the CNN. The skip-connection architecture may instead allow the output of one layer to be connected to the input of a non-sequential layer.

Table 1 below illustrates an exemplary structure that may be used by the CNN for one branch that may comprise a design having 8,468,784 parameters.

TABLE 1

| | | | Kernel | Activa- |
|---|---|---|---|---|
| Layer | Size-in | Size-out | Size | tion |
| Convolutional 1 | 256 × 256 × 3 | 256 × 256 × 16 | 3 × 3 × 16 | Relu |
| Max Pooling | 256 × 256 × 16 | 128 × 128 × 16 | — | — |
| Convolutional 2 | 128 × 128 × 16 | 128 × 128 × 32 | 3 × 3 × 32 | Relu |
| Convolutional 3 | 128 × 128 × 32 | 128 × 128 × 32 | 3 × 3 × 32 | Relu |
| Max Pooling | 128 × 128 × 32 | 64 × 64 × 32 | — | — |
| Convolutional 4 | 64 × 64 × 32 | 64 × 64 × 48 | 3 × 3 × 48 | Relu |
| Convolutional 5 | 64 × 64 × 48 | 64 × 64 × 48 | 3 × 3 × 48 | Relu |
| Max Pooling | 64 × 64 × 48 | 32 × 32 × 48 | — | — |
| Convolutional 6 | 32 × 32 × 48 | 32 × 32 × 64 | 3 × 3 × 64 | Relu |
| Max Pooling | 32 × 32 × 64 | 16 × 16 × 64 | — | — |
| Flatten | 16 × 16 × 64 | 16384 | — | — |
| Dropout | — | — | — | — |
| Dense | 16384 | 128 | — | — |

As illustrated, the CNN may include one or more convolutional layers, one or more max pooling layers, a flattening layer, a dropout layer and a dense layer (i.e., fully connected or linear layer). The size of the data input into each layer of the CNN (i.e.., “Size-in”) and the corresponding size of the data output by a given layer of CNN (i.e., “Size-out”). It is contemplated that the kernel size for each convolutional layer can vary, but it is also contemplated that the kernel sizes may be the same depending on a given application. The CNN may also employ a ReLU activation function for each convolutional layer. It is contemplated, however, that the activation function may vary based on a given application and the CNN may employ other known activation functions (e.g., a tanh activation function).

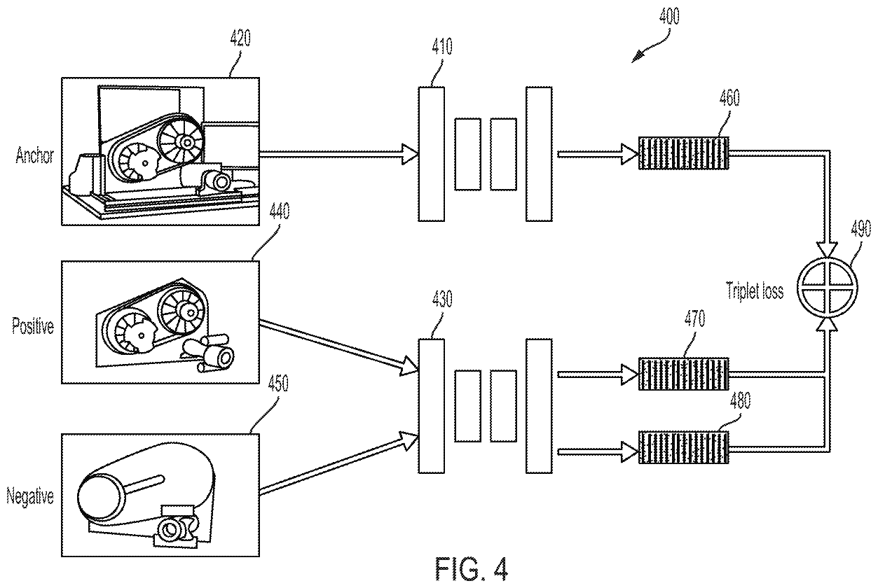

FIG. 4 illustrates a two-branch. CNN 400 that may be employed during a training phase. It is contemplated that CNN 400 may be designed according to the architecture illustrated by FIG. 4. It is also contemplated that the number of layers, size of each layer, and activation functions may vary depending on a given application.

CNN 400 may include an RGB network 410 branch that may receive an anchor image 420 as input data (e.g., RGB image 113). The RGB network 410 may apply the function f_{RGB} that represents the branch of the CNN for feature encoding one of the RGB images 113. The CNN 400 may also include a branch having a normalization network 430 that may receive as input data a positive image 440 and negative image 450 (e.g., one of the 3D-CAD models stored within database 128).

The output data of the RGB network 410 may be provided to an RGB encoded feature 460. Also, the output data of the normalization network 430 may be provided to a positive encoded feature 470 and negative encoded feature 480. The triplet loss algorithm 490 (discussed with reference to Equation 1 above) may then be employed to decrease the vector distance between the anchor image 420 and the positive image 440 and increase the vector distance between the anchor image 420 and negative image 450.

It is contemplated that the normalization network 430 may be implemented as a “Siamese Network” that is able to operate in tandem to compute different vector distances for the positive image 440 and negative image 450 provided. It is also contemplated that RGB network 410 and normalization network 430 may include different layers (i.e. convolutional layers, max pooling layers, flattening layers, dropout layers, realization layers, and dense layers) that employs different training data depending on a given application.

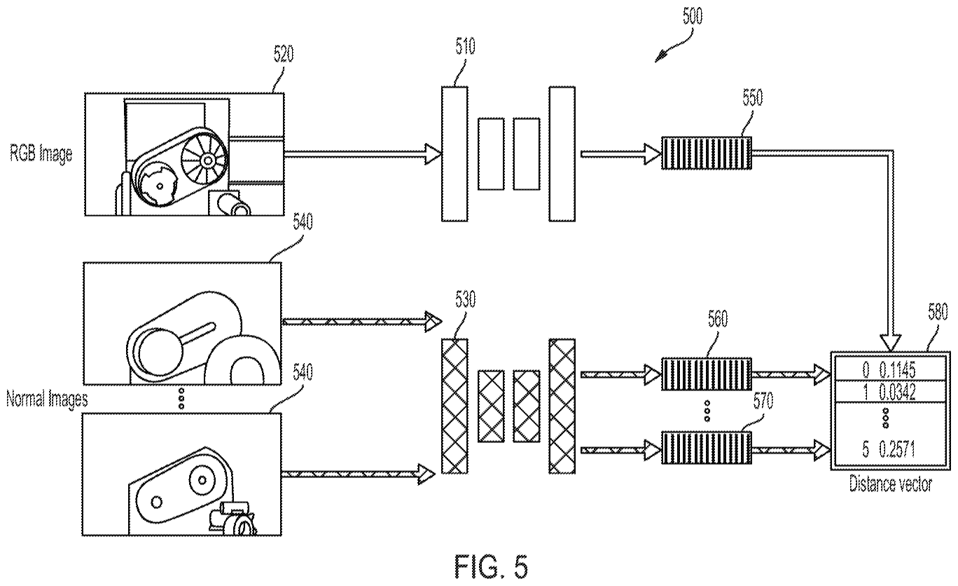

FIG. 5 illustrates CNN 500 that may be employed during a testing phase or during run-time operation. CNN 500 may again be designed using a “Siamese Network,” but it is contemplated that other network designs may be used depending on a given application. It is contemplated that RGB network 510 and normalization network 530 may include different variation of convolutional layers, max pooling layers, flattening layers, dropout layers and dense layers depending on a given application.

RGB network 510 (i.e., f_{RGB}) may be provided an RGB image 520 as an input. Again, the RGB image 520 may be an the RGB image 113 received from client system 110. CNN 500 may also include a normalization network 530 (f_{normalization}) that receives one or more normalized images 540 extracted during the training phase. RGB network 510 may provide output vector data to an RGB encoded feature 550 and normalization network 530 may provide output vector data to one or more normal encoded features 560, 570.

CNN 500 may then use the output vector data provided by RGB encoded feature 550 and the one or more normal encoded features 560, 570 to compute a set of distance vectors 580 from the feature vectors of the normalized images 540 and the feature vectors encoded within RGB image 520. CNN 500 may then select the distance vector that has the smallest distance in the semantic space.

Again, it is also contemplated that CNN may be operable to detect an “invalid” status which indicates that a given step or sequence being performed by a user may not match any step in the procedure. The CNN may determine that the invalid status may have been the result of an incorrect sequence of operations performed by the user. It is contemplated by analyzing the RGB image 113 acquired by client system 110, the CNN may be able to analyze the critical parts of a procedure to recognize an invalid status.

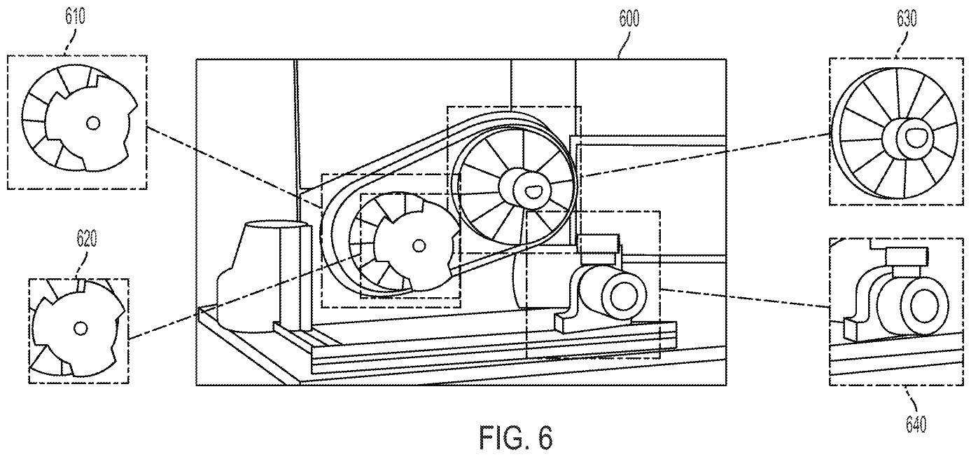

FIG. 6 illustrates an RGB image 600 that may be acquired by client system 110 and transmitted to server system 120. Controller 124 may process the RGB image 600 to detect unexpected parts due to invalid operations by a user. For instance, controller may apply an image cropping algorithm to generate a first bounding box 610, second bounding box 620, third bounding box 630, and fourth bounding box 640 using the RGB image 600 for the presence or absence of parts. CNN may then determine based on the presence or absence of parts within RGB image 600 whether an invalid status exists. Or CNN may determine based on the presence or absence of parts within RGB image 600 whether the user has performed an incorrect step.

It is contemplated that the presence or absence of parts within RGB image 600 may be processed using the two-branch CNN network that is trained using the triplet loss algorithm discussed with respect to FIG. 4. It is contemplated that the controller 124 may be operable to apply an image cropping algorithm that uses one or more 3D-CAD models stored within database 128 to generate one or more 3D-bounding boxes (e.g., first bounding box 610) for what might be pre-programmed as being an essential or critical part. It is contemplated that when training and testing CNN, the 3D-bounding boxes may be projected to the image space based on the current pose. It is also contemplated that the a 2-dimensional projection of the 3D-bounding boxes may be used by CNN to define a region of interest within RGB image 600 that may include certain parts. The parts may be generated by CNN by cropping the RGB image 600 and rendering the cropped images based on a predefined region of interest.

It is also contemplated that CNN may use one of the 3D-bounding boxes (e.g., first bounding box 610) as an anchor image. It is also contemplated that the anchor image and a negative and positive image provided by database 128 is used to train CNN 400 to employ the invalid step recognition process. During the training phase, the anchor image and positive image may contain the same part while the negative image may contain a part that is not the same as the anchor image. It is contemplated that the triplet loss algorithm may again be employed using the anchor image, positive image and negative image to train CNN 400 for determining when a part is detected or absent within a given region of interest.

Once trained, CNN 500 may be employed during a testing phase or run-time operation to provide invalid or incorrect step detection. The testing or run-time operation may crop a captured image (e.g., RGB image 113 received by client system 110) into different parts. CNN may then be operable to compare the parts in the image with. the corresponding areas in two or more two normal map images. It is contemplated that the one normal snap image may include the part and the other normal image may not include the part. If the feature extracted from the image is closer to the normal map image with the part, the CNN may determine that the part is DETECTED. If the feature extracted from the image is closer to the normal map image without the part, the CNN may determine that the part is not detected (i.e., NONE).

Table 2 below illustrates the outputs that may be generated by CNN 500 during the invalid step recognition process.

TABLE 2

| Image | Part 1 | Part 2 | Part 3 | Part 4 | Part 5 | Prediction |
|---|---|---|---|---|---|---|
| 1 | DETECTED | DETECTED | NONE | NONE | NONE | Status 1 |
| 2 | NONE | NONE | DETECTED | DETECTED | DETECTED | Status 2 |
| 3 | NONE | NONE | NONE | DETECTED | DETECTED | Status 3 |
| 4 | NONE | NONE | DETECTED | NONE | DETECTED | Invalid |
| | | | | | | status |

As illustrated, the CNN 500 may employ the invalid step recognition process on more than one image (e.g., image 1, image 2, image 3, image 4). For instance, Table 2 illustrates that for “image 1” the CNN 500 may generate the following outputs for “part 1” to “part 5”: [DETECTED, DETECTED, NONE, NONE, NONE]. Based on these outputs, the invalid step recognition process may be operable to map the outputs to standard repair steps. As shown, for image 1, image 2, and image 3 the invalid step recognition process determined that no invalid step had occurred. Stated differently, for image 1 to image 3 the CNN 500 had determined that the user had been following the repair steps in the correct sequence.

For image “4,” however, the invalid step recognition process had determined that an “Invalid Status” had occurred. The invalid status output may have been generated because the user had mistakenly performed the repair sequence incorrectly. For instance, the fourth step in the repair sequence may have required that “part 1” be “DETECTED.” Since the CNN 500 did not detect “part 1” as being present, an invalid sequence was detected. Alternatively, the invalid status may also be generated if a user has incorrectly tried to re-add a part out of the correct repair sequence. For instance, “part 1” may have been detected as not being present for image 5 because it is currently behind or blocked by an additional part (e.g., part 5). Since, “part 1” is not visible, the invalid step recognition process may still output an “invalid status” because “part 5” was not required to be reassembled until later in the repair sequence.

The processes, methods, or algorithms disclosed herein can be deliverable to/implemented by a processing device, controller, or computer, which can include any existing programmable electronic control unit or dedicated electronic control unit. Similarly, the processes, methods, or algorithms can be stored as data, logic, and instructions executable by a controller or computer in many forms including, but not limited to, information permanently stored on non-writable storage media such as ROM devices and information alterably stored on writeable storage media such as floppy disks, magnetic tapes, CDs, RAM devices, and other magnetic and optical media. The processes, methods, or algorithms can also be implemented in a software executable object. Alternatively, the processes, methods, or algorithms can be embodied in whole or in part using suitable hardware components, such as Application Specific Integrated Circuits (ASICs), Field-Programmable Gate Arrays (FPGAs), state machines, controllers or other hardware components or devices, or a combination of hardware, software and firmware components.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may he combined to form further embodiments of the invention.

What is claimed is:

1. A convolutional neural network (CNN) method comprising:
generating an anchor vector in a semantic space in response to an anchor image being provided to a first CNN, wherein the anchor image is a two-dimensional RGB image, wherein the first CNN includes one or more first convolutional layers, one or more first max pooling layers, a first flattening layer, a first dropout layer, and a first fully connected layer;
generating a positive vector and negative vector in the semantic space in response to a negative image and a positive image being provided to a second CNN, wherein the negative image is a first three-dimensional CAD image and the positive image is a second three-dimensional CAD image, wherein the second CNN includes one or more second convolutional layers, one or more second max pooling layers, a second flattening layer, a second dropout layer, and a second fully connected layer; and
applying a cross-domain deep metric learning algorithm that is operable to extract image features in the semantic space using the anchor vector, positive vector, and negative vector.

2. The method of claim 1, wherein the cross-domain deep metric learning algorithm is a triplet loss algorithm that is operable to decrease a first distance between the anchor vector and the positive vector in the semantic space and increase a second distance between the anchor vector and the negative vector in the semantic space.

3. The method of claim 1, wherein the one or more first convolutional layers and one or more second convolutional layers are operable to apply one or more activation functions.

4. The method of claim 3, wherein the one or more activation functions are implemented using a rectified linear unit.

5. The method of claim 3, wtherein the first CNN and second CNN further include one or more normalization layers.

6. The method of claim 1, wherein the second CNN is designed using a Siamese network.

7. The method of claim 1, wherein the first CNN and second CNN employ a skip-connection architecture.

8. The method of claim 1 further comprising: performing step recognition by analyzing the image features extracted in the semantic space.

9. The method of claim 1 further comprising: determining if an invalid repair sequence has occurred based on an analysis of the image features in the semantic space.

10. An augmented reality system comprising:
a visualization device operable to acquire one or more RGB images; and
a controller operable to,
responsive to an anchor image being provided to a first CNN, generating an anchor vector in a semantic space, wherein the anchor image is a two-dimensional RGB image, wherein the first CNN includes one or more first convolutional layers, one or more first max pooling layers, a first flattening layer, a first dropout layer, and a first fully connected layer;
responsive to a negative image and positive image being provided to a second CNN, generating a positive vector and negative vector in the semantic space, wherein the negative image is a first three-dimensional CAD image and the positive image is a second three-dimensional CAD image, wherein the second CNN includes one or more second convolutional layers, wherein the second CNN includes one or more second convolutional layers, one or more second max pooling layers, a second flattening layer, a second dropout layer, and a second fully connected layer; and
apply a cross-domain deep metric learning algorithm that is operable to extract image features in the semantic space using the anchor vector, positive vector, and negative vector.

11. The augmented reality system of claim 10, wherein the controller is further operable to determine a pose of an image object within the one or more RGB images.

12. The augmented reality system of claim 10, wherein the controller is further operable to decrease a first distance between the anchor vector and the positive vector in the semantic space and increase a second distance between the anchor vector and the negative vector in the semantic space.

13. The augmented reality system of claim 10, wherein the controller is further operable to apply a post-processing image algorithm to the one or more RGB images.

14. The augmented reality system of claim 10, wherein the controller is further operable to determine a current step of a work. procedure.

15. The augmented reality system of claim 14, wherein the controller is further operable to display instructions to the visualization device based on the current step of the work procedure.

16. The augmented reality system of claim 10, wherein the second CNN is designed using a Siamese network.

17. An augmented reality method comprising:
generating an anchor vector in a semantic space in response to an anchor image being provided to a first CNN, wherein the anchor image is a two-dimensional RGB image, wherein the first CNN includes one or more first convolutional layers, one or more first max pooling layers, a first flattening layer, a first dropout layer, and a first fully connected layer;
generating a positive vector and negative vector in the semantic space in response to a negative image and positive image being provided to a second CNN, wherein the negative image is a first three-dimensional CAD image and the positive image is a second three-dimensional CAD image, wherein the second CNN includes one or more second convolutional layers, one or more second max pooling layers, a second flattening layer, a second dropout layer, and a second fully connected layer; and
extracting one or more image features from different modalities using the anchor vector, positive vector, and negative vector.

18. The method of claim 17 further comprising applying a triplet loss algorithm that is operable to decrease a first distance between the anchor vector and the positive vector in the semantic space and increase a second distance between the anchor vector and the negative vector in the semantic space.

19. The method of claim 17 further comprising: performing step recognition by analyzing the image features extracted in the semantic space.

20. The method of claim 17 further comprising: determining if an invalid repair sequence has occurred based on an analysis of the image features in the semantic space.
